(19) United States
(12) Patent Application Publication
(10) Pub. No.: US 2026/0018526 A1
(43) Pub. Date: Jan. 15, 2026

(54) CHIPLET PACKAGE HAVING AN INTERCONNECTING DIE

(71) Applicant: Advanced Micro Devices, Inc., Santa Clara, CA (US)

(72) Inventor: Kong Toon NG, Hsinchu (TW)

(21) Appl. No.: 18/773,419

(22) Filed: Jul. 15, 2024

(51) Int. Cl. H01L 23/538; H01L 21/48; H01L 21/56; H01L 23/00; H01L 23/16; H01L 23/31; H01L 23/48; H01L 25/065

(52) U.S. Cl. CPC H01L 23/5386; H01L 21/4853; H01L 21/56; H01L 23/16; H01L 23/3128; H01L 23/481; H01L 24/16; H01L 23/5389; H01L 24/32; H01L 24/73; H01L 25/0652; H01L 2224/16225; H01L 2224/32225; H01L 2224/73204; H01L 2924/1431

(57) ABSTRACT

Disclosed herein is a multi-die device, and an integrated chip package assembly having the multi-die device. The multi-die device includes a first IC die and a second IC die disposed at a same tier; a first conductive pillar coupled with the first IC die; a second conductive pillar coupled with the second IC die; and an interconnecting die disposed between the first conductive pillar and the second conductive pillar and configured to couple with the first IC die and the second IC die. The multi-die device further includes a first interconnecting interface disposed on the first IC die; a second interconnecting interface disposed on the second IC die, the first interconnecting interface and the second interconnecting interface being separated by a molding material.

### TECHNICAL FIELD

Embodiments of the present invention generally relate to a chip package having an interconnecting die, and in particular, to a chip package integrated with an interconnected die and fan-in structures.

### BACKGROUND

Electronic devices, such as tablets, computers, copiers, digital cameras, smart phones, control systems and automated teller machines, among others, often leverage chip package assemblies for increased functionality. To increase processing capabilities, packaging designs often form a die stack by vertically mounting a plurality of integrated circuit (IC) dies to a package substrate. An integrated chip package may include IC dies for memory, logic, communication, power management, or other functions.

In a chip package, high bandwidth communications among the IC dies and with external devices often occur. Interconnecting dies may be included in a chip package to provide such high bandwidth communications. Redistribution layers (RDL) may also be included in the chip package to provide fan-in and fan-out structures. Conventional processes and structures for integrating the IC dies, interconnected dies, and RDLs involve many steps that result in low yield and high cost.

Therefore, a need exists for an improved chip package having simplified process flows.

### SUMMARY

Disclosed herein are a multi-die device, an integrated chip assembly having the multi-die device, and a method for making the integrated chip assembly. In an embodiment, the multi-die device includes a first integrated circuit (IC) die and a second IC die disposed at a same tier; a first conductive pillar coupled with the first IC die; a second conductive pillar coupled with the second IC die; and an interconnecting die disposed between the first conductive pillar and the second conductive pillar and configured to couple with the first IC die and the second IC die. In one example, the first and second IC dies are chiplets. The first and second conductive pillars include testing structures used for testing the first die and the second die in a testing process to identify a Known Good Die. The multi-die device further includes a first interconnecting interface disposed on the first IC die; a second interconnecting interface disposed on the second IC die, the first interconnecting interface and the second interconnecting interface being separated by a molding material.

In another embodiment, the integrated chip package assembly includes a multi-die device; and a package substrate coupled with the multi-die device. The multi-die device is configured as set forth in the present disclosure.

In another embodiment, the method for making an integrated chip assembly includes disposing a first IC die and a second IC die at a same tier, the first IC die comprising a first conductive pillar disposed adjacent to an edge of the first IC die, the second IC die comprising a second conductive pillar disposed adjacent an edge of the second IC die; arranging the first IC die and the second IC die such that the first conductive pillar and the second conductive pillar are placed away from each other, an empty space being created between the first conductive pillar and the second conductive pillar; disposing an interconnecting die within the empty space; and connecting the interconnecting die with the first IC die and the second IC die. The first die further includes a first interconnecting interface, and the second die further includes a second interconnecting interface, the first interconnecting interface and the second interconnecting interface being separated.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic cross-sectional view of an electronic device having an integrated circuit die stack, according to an embodiment of the present application.

FIG. 2a illustrates a schematic close-up view of a multi-die device arranged in the integrated circuit die stack, according to an embodiment of the present application.

FIG. 2b illustrates interconnecting interfaces of the multi-die device 128, according to an embodiment.

FIG. 2c illustrates a multi-die device mounted on a package substrate, according to an embodiment.

FIG. 3 illustrates a schematic process flow to determine a functional die, according to an embodiment of the present application.

FIG. 4 illustrates a schematic process flow to integrate functional dies with an interconnecting die, according to an embodiment of the present application.

FIG. 5 illustrate a method for making a chip package, according to an embodiment.

To facilitate understanding, identical reference numerals have been used, where possible, to designate identical elements that are common to the figures. It is contemplated that elements of one embodiment may be beneficially incorporated in other embodiments.

### DETAILED DESCRIPTION

The present disclosure provides a simplified, low cost, and high yielding package structure for integrating high bandwidth integrated circuit (IC) dies with an interconnecting die. The package structure includes two IC dies coupled by an interconnecting die. The package structure may also be referred to as a multi-die device. The two IC dies may be configured as chiplets. A chiplet is an IC that contains a well-defined subset of functional circuitry. The chiplets are specifically designed to communicate with each other, thus forming a larger more complex IC block. As set forth in various embodiments of the present disclosure, each IC die includes an interconnecting interface disposed within a perimeter of the IC die. The interconnecting interface is configured to couple the IC die with another device, such as an interconnecting die. Comparing to conventional devices, the interconnecting interface of the present disclosure is formed by a lesser amount of polymer layers and metal layer, thus reducing cost and simplifying the process for integration. In an example, the interconnecting interface may include only a single polymer layer.

In an example, the interconnecting interface may couple the IC die with a conductive pillar, which may function as vias for transmitting power signals, ground signals, or any other signals to another device. The conductive pillar may be made of a metal, such as Cu, gold, or any other suitable conductive material. To take advantage of a testing process for testing a Known Good Die, the conductive pillar may include a testing structure, which is used to test the functionality of the functional circuitry disposed within the IC die. The testing structures may include Cu posts that have a pitch of at least 130 μm (C4 pitched Cu posts). The package structure utilizes the testing structures as a first set of vias for connecting the IC dies with another source. The interconnecting die is configured to be disposed between the testing to save the footprint of the package structure. The interconnecting die also has a similar height as the testing structures to ease fabrication.

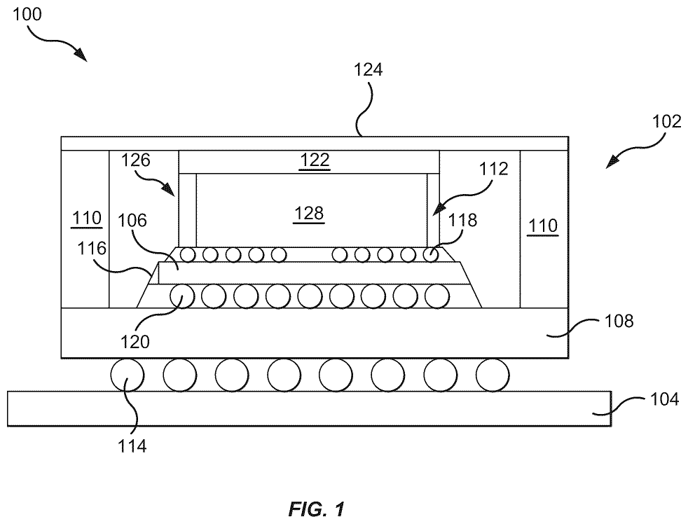

FIG. 1 illustrates a schematic configuration of an electronic device 100, according to one or more embodiments. The electronic device 100 may be a tablet, computer, copier, digital camera, smart phone, control system, automobile control, automated teller machine, server or other solid-state memory and/or logic device. The electronic device 100 includes a chip package 102 mounted on a printed circuit board (PCB) 104. The chip package 102 may be connected with the PCB 104 via a plurality of electric connections 114, such as solder balls or other suitable connections.

The chip package 102 includes a chip stack 126 having a plurality of integrated circuit (IC) dies. The plurality of IC dies, such as one or more chiplets, may be arranged in tiers, such as two, three, four, or even a greater number of tiers. Each tier may include one or more of the IC dies. The interconnection among IC dies of the different tiers may include hybrid bonds, micro solder balls, or any other suitable interconnect. Each IC die may be a CPU, GPU, programmable logic devices, such as field programmable gate arrays (FPGA), memory devices, optical devices, processors or other IC logic structures.

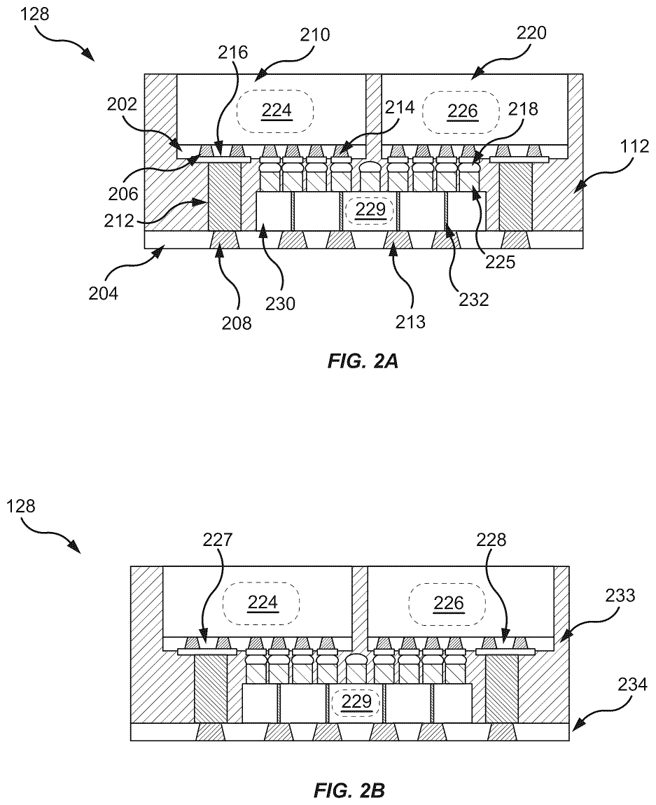

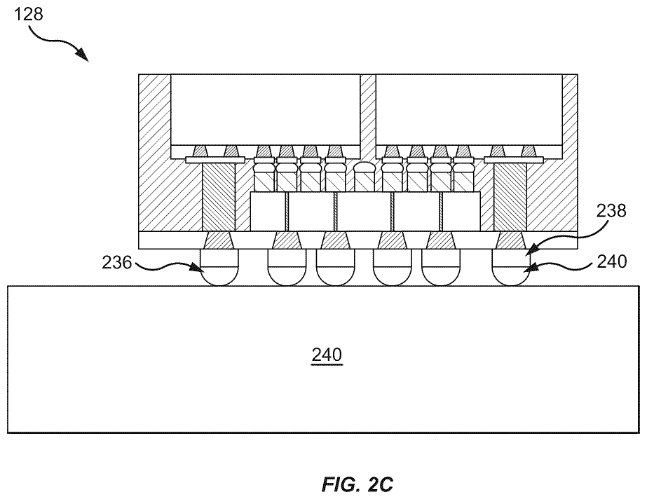

According to an embodiment, the chip stack 126 includes a multi-die device 128 configured to integrate a plurality of IC dies with an interconnecting die. Interconnecting interfaces are included in the multi-die device 128 to provide fan-in and fan-out structures for the IC dies and provide connections between the multi-die device and other IC dies or devices. The multi-die device 128 may include a molding material 112 encasing the IC dies and the interconnect die. The multi-die device 128 is described below with reference to FIGS. 2a and 2b.

Continuing to refer to FIG. 1, the chip stack 126 may be mounted to a top surface of an interposer 106 by die connections 118. The die connections 118 may be in the form of a plurality of solder joints, also known as “micro-bumps” or “C4 bumps.” The interposer 106 includes a circuitry for electrically connecting the chip stack 126 to a circuitry of the package substrate 108. Solder connections 120, also known as or “package bumps” or “C4 bumps,” are utilized to provide an electrical connection between the circuitry of the interposer 106 and the circuitry of the package substrate 108.

The interposer 106 may be optional in the chip stack 126. For example, the chip stack 126 may be mounted directed to a package substrate 108. The package substrate 108 may be mounted and connected to the PCB 104, utilizing electrical connections 114, such as solder balls, or other suitable technique.

The chip package 102 further includes an optional stiffener 110 coupled with the package substrate 108 and configured to enhance the warpage resistance of the package substrate 108 against out of plane deformation. The chip package 102 further includes a lid 124 coupled with the stiffener 110 and configured to cover the chip stack 126. The lid 124 is capable of dissipating heats generated by the chip package 102. A filler die 122 may be disposed within the chip stack 126 to fill a space between the multi-die device 128 and the lid 124. An under molding 116 may be utilized to fill the space not taken by the solder connections 120 between the interposer 106 and the chip stack 126 or the package substrate 108.

FIG. 2a illustrates a schematic configuration of the multi-die device 128, according to an embodiment. FIG. 2b illustrates various distribution layers of the multi-die device 128 of FIG. 2a. Comparing to conventional devices, the multi-die device 128 has an improved interconnecting interface 233 between the IC die 224 and the interconnecting die 229. The interconnecting interface 233 is formed by taking advantages of parts and structures used by other processes. As a result, the interconnecting interface 233 may have a lesser amount of polymer layers and/or metal layers than the conventional devices. In one embodiment, the interconnecting interface 233 includes only a single polymer layer. In another embodiment, the interconnecting interface 233 is formed by combining a testing structure used in a testing process and an existing layer deposited on the IC die before the testing process. In this manner, the cost and process for making the interface layer 233 are reduced.

The multi-die device 128 may include a plurality of IC dies connected by interconnecting dies. For example, FIG. 2a shows two IC dies 210 and 220 connected by an interconnecting die 230. In one example, the IC dies 210, 220 are configured as chiplets. The IC die 210 and the IC die 220 are arranged at the same tier and are not directly connected with each other. The interconnecting die 230 is arranged at a tier that is higher or lower than the dies 210 and 220. The dies 210, 220 may be fabricated by processes that are the same as or different from processes to make the interconnecting die 230. The dies 210, 220 and the interconnecting die 230 are integrated after the IC dies and the interconnecting die are made, tested, and singularized.

In an embodiment, the multi-die device 128 also includes a plurality of testing structures 212 disposed at the perimeters of the multi-die device 128. The testing structures 212 provide additional vertical connections between the dies 210, 220 with another source or device.

The IC die 210 may include one or more integrated circuits 224, and the IC die 220 may include one or more integrated circuits 226. The integrated circuits 224 may be configured to perform the same or different functions as the integrated circuits 226. The integrated circuits 224, 226 may function as programmable logic devices, such as field programmable gate arrays (FPGA), memory devices, CPUs, GPUs, optical devices, processors or other IC logic structures.

The interconnecting die 230, which is also known as a bridge die, may include a plurality of through silica vias (TSV) 232. The TSVs 232 can provide vertical connectivity and can be configured to transfer several types of signals, including power, ground connection, data signal, testing signals, control signal, timing signal, encryption signal, or any other signals transmitted from a die to another die. Having TSVs in the interconnecting die increases design flexibility as vertical connections among IC dies in different tiers can be additionally routed through TSVs of the interconnecting die.

The interconnecting die 230 may also include an integrated electrical circuit 229, which may be an active device or a passive device, such as capacitors, inductors, and active circuitries. For example, the interconnecting die 230 may include an integrated capacitor to improve power and signal integrity of signals transmitted by the interconnecting die 230. The integrated electrical circuit 229 of the interconnecting die 230 may also include one or more active devices such as diodes, rectifiers, varactors, transistors, thryistors and the like. In an embodiment, the active devices may function as a memory controller circuitry, including an on-package memory controller and an off-package memory controller.

The interconnecting die 230 may further include a plurality of posts 225 and electrical connections 218. The plurality of posts may be made of conductive materials, such as Cu. The electrical connections 218 may include micro bumps or hybrid bonds.

As shown in FIG. 2a, the multi-die device 128 includes internal connections configured to simplify the fabrication process. In an embodiment, each of the dies 210 and 220 includes an interconnecting interface disposed within the perimeter of a respective IC die, which may function as a redistribution layer for fan-in or fan-out connections. For example, the IC die 210 has an interconnecting interface 227 (shown in FIG. 2b), which is disposed on the surface of the IC die 210 and does not extend beyond the perimeters of the IC die 210. The interconnecting interface 227 is connected with the interconnecting die 230. The interconnecting interface 227 includes a dielectric layer 202, a plurality of first pillars 214, a plurality of second pillars 206, and bond pads 216. The dielectric layer 202 is configured to provide a general isolation between the IC die 210 and the interconnecting die 230. The dielectric layer 202 may be made of polymeric materials, such as polyimide (PI), polybenzoxazole (PBO), benzocylobutene (BCB), or any other suitable materials. The pillars 214 and 206 are configured to provide electrical connection between the dies 210, 220 and other sources.

The IC die 220 has a interconnecting interface 228 (shown in FIG. 2b). The interconnecting interface 228 is connected with the interconnecting die 230. The interconnecting interface 228 may be similarly configured as the interconnecting interface 227. In an embodiment as shown in FIG. 2a, the interconnecting interface 227 of the IC die 210 and the interconnecting interface 228 of the IC die 220 are separated by the molding material 112.

The interconnecting interfaces 227 and 228 are configured to provide fan-in and/or fan-out structures for the dies 210 and 220. For example, the first plurality of pillars 214 are configured to connect the IC dies 210 and 220 with the interconnecting die 230. The first plurality of pillars 214 are coupled with the bond pads 216, which, in turn, couple with the electrical connection 218 of the interconnecting die 230. In an embodiment, the first plurality of pillars 214 and the bond pads 216 are made of copper or any other suitable conductive materials. The second plurality of pillars 206 are configured to connect the dies 210 and 220 with the testing structures 212, which, in turn, is coupled with other sources or devices.

To form planar surfaces for stacking IC dies vertically, the plurality of pillars 214, 206 and the dielectric layer 202 are disposed in a same layer and have the same height. The interconnecting die 230 and the testing structures 212 are disposed in a same layer and have the same height. The empty spaces among the dies 210, 220, the interconnecting die 230, and the testing structure 212 are filled with the molding material 112. The molding material 112 also encases the dies 210 and 220 for protection.

As shown in FIG. 2b, the multi-die device 128 also includes an interconnecting interface 234 configured to provide connections between the multi-die device 128 and another source or device. To make the interconnecting interface 234 (shown in FIG. 2b) on a surface of the multi-die device 128, a dielectric layer 204 is disposed on the surface formed by the interconnecting die 230, the molding material 112, and the testing structures 212. The dielectric layer 204 is configured to provide a general isolation between the multi-die device 128 and another source. A plurality of pillars 208 and 213 are disposed in the dielectric layer 204 to provide electrical connections. The pillars 208 are configured to couple the testing structures 212 with another source (for example via a test probe), while the pillars 213 are configured to couple the TSVs 232 of the interconnecting die 230 with another source. The pillars 208 and 213 may be made of similar materials as those of the pillars 206 and 214.

The multi-die device 128 as shown in FIG. 2a provides a simplified and compact configuration to integrate dies 210 and 220 with the interconnected die 230. For example, by disposing the interconnecting die 230 inside the testing structure 212, the integration does not extend a footprint of the multi-die device 128 beyond the footprint of the dies 210 and 220. The interconnecting die 230 with the TSVs 232 and integrated circuits 229 can function as a fan-in or fan-out structure for the dies 210 and 220. The interconnecting die 230 can also provide a high bandwidth lateral connection between the IC die 210 and the IC die 220.

Now turning to FIG. 2b, which illustrates interconnecting interfaces of the multi-die device 128, according to an embodiment, the multi-die device 128 includes two interconnecting interfaces 233 and 234 (other reference numerals are not shown for brevity.). The first interconnecting interface 233 is disposed on the surface of the dies 210 and 220 and include the interconnecting interfaces 227, 228. The first interconnecting interface 233 provides connections between the dies 210, 220 and other devices, such as connections between the IC dies and the interconnecting die 230 and connections between the IC dies and the testing structure 212. The second interconnecting interface 234 is disposed on a surface of the multi-die device 128, which covers the interconnecting die 230, the testing structure 212, and the molding material 112. The second interconnecting interface 234 is disposed opposite to the first interconnecting interface 223 with regard to the interconnecting die 230. The second interconnecting interface 234 is configured to provide connections between the multi-die device 128 and another source or device.

FIG. 2c illustrates a schematic cross-sectional view of a multi-die device 128 mounted on a package substrate 240, according to an embodiment. The multi-die device 128 may be coupled with the package substrate 240 via an electrical interface 236. In an embodiment, the electrical interface 236 may include a bond pad 238 and a C4 bump. Other electrical connections, such as hybrid bond or any other suitable connections, may be used to couple the multi-die device 128 with the package substrate 240. In another embodiment, the multi-die device 128 may be mounted on a PCB or another electronic structure, such as an IC die or a chip stack.

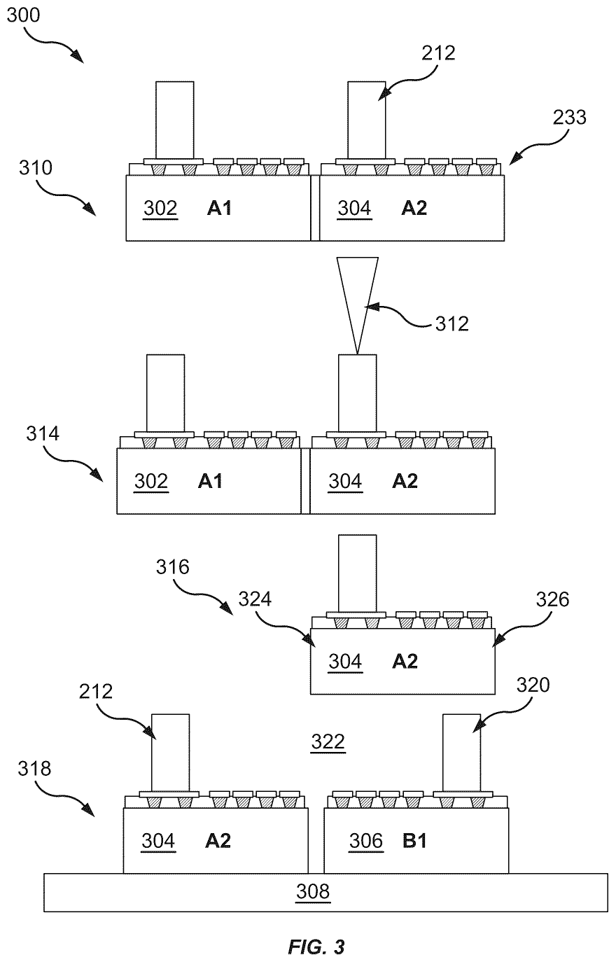

FIG. 3 illustrates a process flow 300 for preparing the IC dies and the first interconnecting interface, according to an embodiment. At operation 310, a plurality of IC dies 302 and 304 are formed in a common substrate by any suitable processes. The plurality of IC dies 302 and 304 may be configured to perform an identical function or different functions. Then, the first interconnecting interface 233 is formed on a surface of the plurality of IC dies 302 and 304 by any suitable processes. For example, the first interconnecting interface 233 may be formed by depositing one or more layers of dielectric material, forming a plurality of holes and trenches in the dielectric material, and then forming vias and lines in the holes and trenches, an bond pads around the holes by a plating process or other suitable processes, to form electrical routings through the first interconnecting interface 233. In an embodiment, the first interconnecting interface 233 is formed on an active surface of the IC dies 302 and 304 and has only a single polymer layer. In an embodiment, a testing structure 212, such as a Cu post, is built together with the interconnecting interface 233. The testing structure 212 is disposed at the peripheral area of the IC die and extending away from an exposed surface of the interconnecting interface 233. The testing structure 212 can be made during the fabrication process for the first distribution layer. The testing structure 212 is connected with testing circuits of the IC die. In an embodiment, the testing structure 212 is disposed only at one side 324 of the IC die. In an embodiment, at least one side 326 of the IC die does not have the testing structure 212.

At operation 314, a probe 312 contacts the testing structure to test the functionality of IC dies 302 and 304. The probe 312 is configured to identify functional IC dies and non-functional IC dies. A functional IC die is an IC die that has test results that meets or exceeds a predetermined level of functionality, is be commonly referred as a known good die (KGD). In FIG. 3, the IC die 304 may be identified as a KGD, while the IC die 302 is identified as a non-functional die. As the testing structure is contacted by the probe 312, the testing structure 212 is arranged on the IC die with sufficient spaces for testing. In an example, the testing structure 212 includes C4 pitched Cu posts.

At operation 316, the IC dies 302 and 304 are separated to produce independent and singularized IC dies. The IC die 304, a KGD, will be integrated in a chip package with other KGD IC dies. In an embodiment, the testing structure 212 is kept on the singularized IC die 304 and will be used to provide electrical connections in a to-be-formed chip package.

At operation 318, the IC die 304 is disposed on a reconstituted carrier 308, to form a reconstituted wafer. Another IC die 306, another KDG, is also disposed on the reconstituted carrier 308. The IC die 306 may be from another substrate and have a different function from the IC die 304. Alternatively, some or all the IC dies 304, 306 may be from the same substrate and perform same or different functions. The IC die 306 also includes an interconnecting interface that has a testing structure 320. The IC dies 304 and 306 are arranged on the reconstituted carrier 308 to be included in the same tier. In an embodiment, when the IC die 304 and 306 are disposed on the reconstituted carrier 308, the two testing structures 212 and 320 are placed at far away from each other. For example, the free sides (no testing structures) of the IC dies 304 and 306 are arranged adjacent to each other, while the testing sides (with the testing structures) of the IC dies are arranged far away from each other. This arrangement generates a central space 322 between the testing structures 212 and 320. The central space 322 can be configured to receive an interconnecting die.

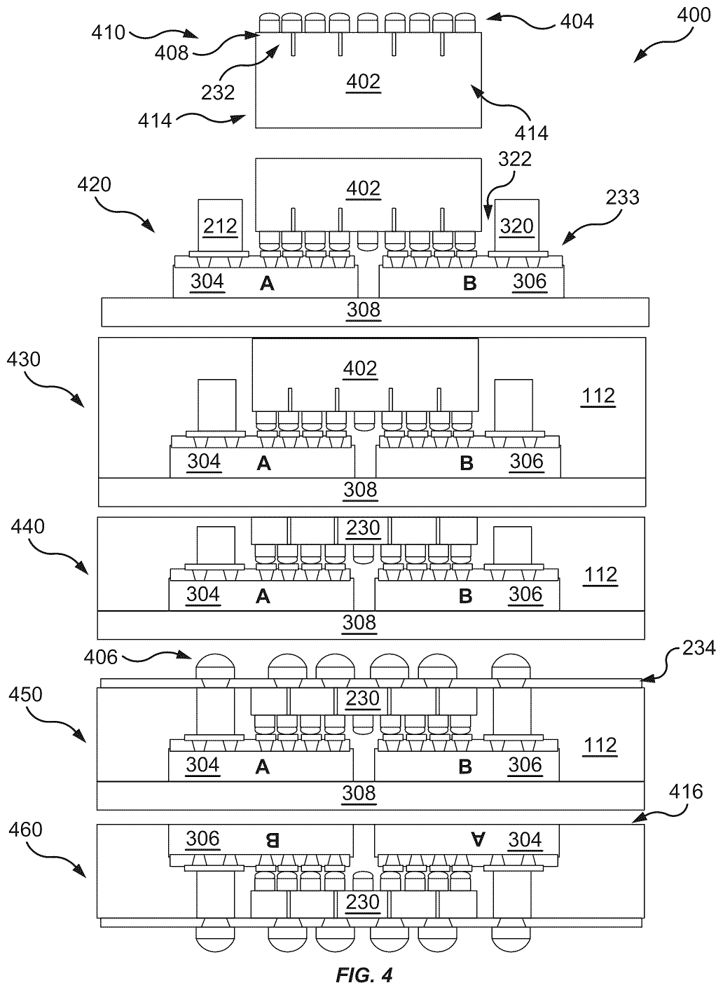

FIG. 4 illustrates a process flow for integrating an interconnecting die 230 with the IC dies 302, 304 shown in FIG. 3, according to an embodiment. At operation 410, a die 402 is fabricated and singularized. Although the IC die 402 includes all components of the interconnecting die 230, such as TSVs 232 and electrical connections 404, the IC die 204 does not function as the interconnecting die 230 because the IC die 402 includes a sacrificial portion 414 at one side 412. The sacrificial portion 414 is disposed at the side 412, opposite to TSVs 232, and will be removed in subsequent processing to expose the TSVs. The removal of the sacrificial portion also makes the height of the IC die 402 the same as other structures of within the same tier, such as the testing structures 212 and 320. The TSVs 232 are disposed at another side 408, which is opposite to the side 412. Passive or active electric components or circuitry may also be disposed at the side 408. On the surface of the side 408, the IC die 402 further includes the electrical connection 404, such as Cu pillars and micro bumps.

At operation 420, the IC die 402 is flipped to have the electrical connection 404 face the interconnecting interface 233 of the IC dies 304 and 306. The IC die 402 is disposed inside the space 322 located between the testing structures 212 and 320. The two interconnecting interfaces of the IC dies 304 and 305 are physically separated. The electric connection 404 of the IC die 402 and the interconnecting interface 233 contact with each other to couple the IC dies 304, 306 with the IC die 402. In an embodiment, the IC die 402 is configured to provide lateral communication between the IC die 304 and the IC die 306. As the IC die 402 and the interconnecting interface 228 may be made of different processes, the height of the IC die 402 and the testing structures 212, 320 of the interconnecting interface 228 may have different heights. A planarization of the surfaces may be carried out such that additional structures or devices may be arranged on the planar surface.

At operation 430, the molding material 112 is used to encase the IC die 402, the interconnecting interface 233, and the IC dies 304 and 306. The molding material 112 provides structural integrity to protect the encased components in subsequent processes. The molding material 112 may be silicon, resin, or epoxy based plastics.

At operation 440, the structure is planarized, such as by chemical mechanical polishing or grinding. For example, the sacrificial portion 414 and molding material 112 encasing the sacrificial portion 414 are removed to expose the testing structures 212, 320 and the TSVs 232. After the sacrificial portion 414 is removed, the IC die 402 can function as the interconnecting die 230.

At operation 450, the second interconnecting interface 234 is disposed on the surfaces of the exposed testing structures 212, 320, the TSVs 232, the interconnection die 230, and the molding material 112. Another electric connection 406 is disposed on the interconnecting interface 234. The electric connection 406 is configured to connect the IC dies 304, 306 with another source or device, such as the package substrate, an IC die, or a PCB. The electric connection 406 may include hybrid bonds, pillars, micro mumps or C4 bumps.

At operation 460, the reconstituted carrier 308 is removed. The multi-die device 128 may be flipped to allow the electric connection 406 to couple with another source or device. The exposed surface 416 of the multi-die device 128 may be configured to couple with other devices, such as IC dies. More redistribution layers may be additionally disposed on the exposed surface 416.

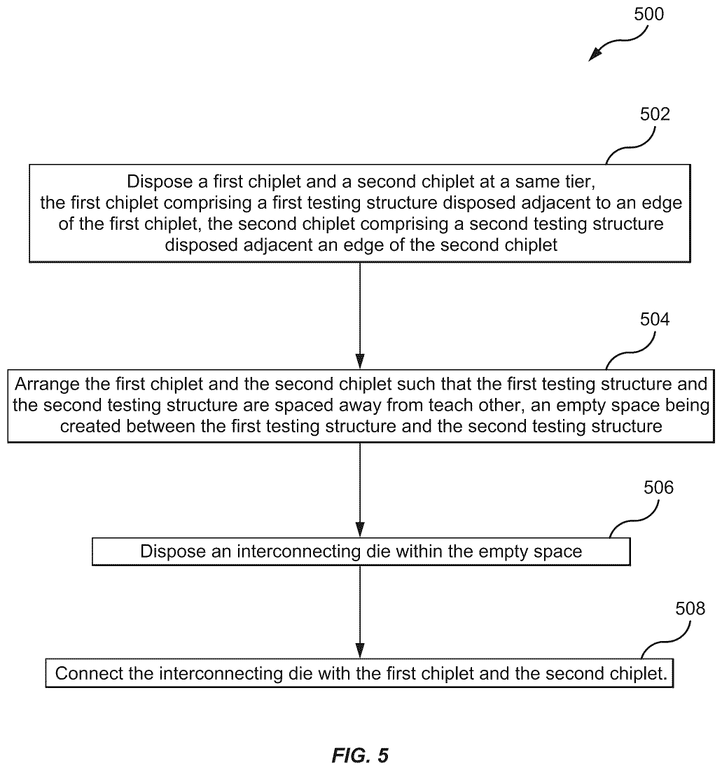

FIG. 5 illustrates a method 500 for making a chip package, according to an embodiment. At operation 502, a first IC die and a second IC die are disposed on a same tier, such as by placing them on a reconstituted carrier. The first IC die includes a first testing structure disposed adjacent to an edge of the first IC die, and the second IC die includes a second testing structure disposed adjacent an edge of the second IC die. At operation 504, the first IC die and the second IC die are arranged such that the first testing structure and the second testing structure are placed away from each other, an empty space being created between the first testing structure and the second testing structure. At operation 506, an interconnecting die is disposed within the empty space. At operation 508, the interconnecting die is connected with the first IC die and the second IC die.

In one or more embodiments, the method further includes operations that disposes interconnecting interfaces on surfaces of the interconnecting die, the first testing structure, and the second testing structure; and/or encases the interconnecting die, the first IC die, and the second IC die with a molding material. The method may further configure the first testing structure and the second testing structure to test functionalities of the first IC die and the second IC die, respectively.

While the foregoing is directed to embodiments of the present invention, other and further embodiments of the invention may be devised without departing from the basic scope thereof, and the scope thereof is determined by the claims that follow.

What is claimed is:

1. A multi-die device comprising:
a first IC die and a second IC die disposed at a same tier;
a first interconnecting interface disposed on the first IC die;
a second interconnecting interface disposed on the second IC die, the first interconnecting interface and the second interconnecting interface being separated by a molding material;
a first conductive pillar coupled with the first IC die;
a second conductive pillar coupled with the second IC die; and
an interconnecting die disposed between the first conductive pillar and the second conductive pillar and configured to couple with the first IC die and the second IC die.

2. The multi-die device of claim 1, wherein the first interconnecting interface couples the first IC die with the first conductive pillar, the second interconnecting interface couples the second IC die with the second conductive pillar.

3. The multi-die device of claim 2,
wherein the first interconnecting interface is formed by a single polymer layer and couples the first IC die with the interconnecting die; and
wherein the second interconnecting interface is formed by a single polymer layer and couples the second IC die with the interconnecting die.

4. The multi-die device of claim 2, wherein the first conductive pillar and the second conductive pillar are configured as a testing structure for testing the first IC die and the second IC die, respectively.

5. The multi-die device of claim 2, further comprising:
a third interconnecting interface disposed on surfaces of the first conductive pillar, the second conductive pillar, and the interconnecting die, the interconnecting die being disposed between the first interconnecting interface and the third interconnecting interface.

6. The multi-die device of claim 5, wherein the third interconnecting interface comprises a third conductive pillar coupling with a through silicon via of the interconnecting die.

7. The multi-die device of claim 6, wherein the third interconnecting interface comprises a fourth pillar coupling with the first conductive pillar.

8. The multi-die device of claim 1, further comprising a molding material filing empty spaces among the first IC die, the second IC die, and the interconnecting die.

9. The multi-die device of claim 1, wherein the first conductive pillar and the second conductive pillar have substantially a same height.

10. The multi-die device of claim 9, wherein the first conductive pillar and the interconnecting die have substantially the same height.

11. The multi-die device of claim 9, wherein the first conductive pillar and the second conductive pillar are configured to test functionalities of the first IC die and the second IC die, respectively.

12. An integrated chip package assembly comprising:
a multi-die device;
a package substrate coupled with the multi-die device; and
,
wherein the multi-die device comprises: a first IC die and a second IC die disposed at a same tier; a first conductive pillar coupled with the first IC die; a second conductive pillar coupled with the second IC die; and an interconnecting die disposed between the first conductive pillar and the second conductive pillar and configured to couple with the first IC die and the second IC die;
wherein the multi-die device further comprises a first interconnecting interface disposed on the first IC die and a second interconnecting interface disposed on the second IC die; and
wherein the first interconnecting interface couples the first IC die with the first conductive pillar, the second interconnecting interface couples the second IC die with the second conductive pillar, and the first interconnecting interface and the second interconnecting interface are separated by a molding material.

13. The integrated chip package assembly of claim 12, further comprising:
a stiffener ring surrounding the multi-die device.

14. The integrated chip package assembly of claim 12,
wherein the first interconnecting interface couples the first IC die with the interconnecting die and is formed by a single polymer layer; and
wherein the second interconnecting interface couples the second IC die with the interconnecting die and is formed by a single polymer layer.

15. The integrated chip package assembly of claim 14, further comprising:
a third interconnecting interface disposed on surfaces of the first conductive pillar, the second conductive pillar, and the interconnecting die, the interconnecting die being disposed between the first interconnecting interface and the third interconnecting interface.

16. The integrated chip package assembly of claim 15, wherein the third interconnecting interface comprises a third pillar coupling with a through silicon via of the interconnecting die and a fourth pillar coupling with the first conductive pillar.

17. The integrated chip package assembly of claim 12, wherein the first conductive pillar and the second conductive pillar have substantially a same height, the first conductive pillar and the interconnecting die have substantially the same height, and the first conductive pillar and the second conductive pillar are configured to test functionalities of the first IC die and the second IC die, respectively.

18. A method for making an integrated chip package assembly, comprising:
disposing a first IC die and a second IC die at a same tier, the first IC die comprising a first conductive pillar disposed adjacent to an edge of the first IC die and a first interconnecting interface, the second IC die comprising a second conductive pillar disposed adjacent an edge of the second IC die and a second interconnecting interface, the first interconnecting interface and the second interconnecting interface being separated from each other;
arranging the first IC die and the second IC die such that the first conductive pillar and the second conductive pillar are placed away from each other, an empty space being created between the first conductive pillar and the second conductive pillar;
disposing an interconnecting die within the empty space; and
connecting the interconnecting die with the first IC die and the second IC die.

19. The method of claim 18 further comprising:
encasing the interconnecting die, the first IC die, and the second IC die with a molding material.

20. The method of claim 18 further comprising:
configuring the first conductive pillar and the second conductive pillar to test functionalities of the first IC die and the second IC die, respectively.
